(19) United States
(12) Patent Application Publication
(10) Pub. No.: US 2026/0140162 A1
(43) Pub. Date: May 21, 2026

(54) SUBSTRATE TESTING APPARATUS

(71) Applicant: Samsung Electronics Co., Ltd., Suwon-si (KR)

(72) Inventors: Wooseong Kim, Suwon-si (KR); Heejin Baek, Suwon-si (KR)

(21) Appl. No.: 19/352,235

(22) Filed: Oct. 7, 2025

(30) Foreign Application Priority Data
Nov. 21, 2024 (KR) 10-2024-0167754
Jan. 17, 2025 (KR) 10-2025-0007551

(51) Int. Cl. G01R 31/26; G01R 1/073; G01R 31/265; G01R 31/28

(52) U.S. Cl. CPC G01R 31/2644; G01R 1/07342; G01R 31/2656; G01R 31/2867

(57) ABSTRACT

Provided is a substrate testing apparatus including a substrate support including a first surface configured to support a substrate and a second surface opposite to the first surface, and a photographing hole penetrating through the first surface and the second surface, a camera arranged below a lower surface of the substrate support, and configured to photograph the skeleton chips through the photographing hole of the substrate support, and a probe device arranged above the substrate and configured to apply a voltage to the skeleton chips. The probe device comprises a probe pin configured to contact a chip bump arranged on an upper surface of a skeleton chip, a probe card in contact with an upper surface of the probe pin, a lower plate arranged under a lower surface of the probe card, and a support protrusion arranged under the lower plate, and configured to be detachable.

### CROSS-REFERENCE TO RELATED APPLICATION

This application is based on and claims priority under 35 U.S.C. §119 to Korean Patent Application Nos. 10-2024-0167754, filed on November 21, 2024, and 10-2025-0007551, filed on January 17, 2025, in the Korean Intellectual Property office, the disclosures of which are incorporated by reference herein in their entireties.

### BACKGROUND

The inventive concept relates to a substrate testing apparatus, and more particularly, to a substrate testing apparatus to test to detect defects of a skeleton chip.

When a manufacture of a semiconductor substrate is completed, processes of testing the semiconductor substrate are performed to detect defects. For example, a hot electron analysis (HEA) test may be performed to test/detect stand-by defects in semiconductor substrates. In the HEA test, the substrate testing apparatus may apply a voltage to a portion of a semiconductor substrate, and photons or heat emitted from the semiconductor substrate may be detected/photographed by using a camera to determine the stand-by defects of the semiconductor substrate.

### SUMMARY

Aspects of the inventive concept provide a substrate testing apparatus having improved reliability.

In addition, the issues addressed by the technical idea of the inventive concept are not limited to those mentioned above, and other issues may be clearly understood by those of ordinary skill in the art from the following descriptions.

According to an aspect of the inventive concept, there is provided a substrate testing apparatus including a substrate support including a first surface configured to support a substrate and a second surface opposite to the first surface, and a photographing hole penetrating through the first surface and the second surface, a camera arranged below the second surface of the substrate support, and configured to photograph skeleton chips through the photographing hole of the substrate support, and a probe device arranged above the substrate support, and configured to apply a voltage to the skeleton chips, wherein the probe device includes a probe pin configured to contact a chip bump arranged on an upper surface of a skeleton chip, a probe card in contact with an upper surface of the probe pin, a lower plate arranged under a lower surface of the probe card, and a support protrusion arranged under the lower plate, and configured to be detachable, and wherein a vertical level of a lower surface of the support protrusion is lower than a vertical level of a lower surface of the probe pin.

According to another aspect of the inventive concept, there is provided a substrate testing apparatus including a substrate support including a first surface configured to support a substrate and a second surface opposite to the first surface, and a photographing hole penetrating the first surface and the second surface, a camera arranged below a second surface of the substrate support, and configured to photograph skeleton chips through the photographing hole of the substrate support, and a probe device arranged above the substrate support, and configured to apply a voltage to the skeleton chips, wherein the probe device includes a probe pin configured to contact a chip bump arranged on an upper surface of a skeleton chip, a probe card in contact with an upper surface of the probe pin, and a lower plate arranged under a lower surface of the probe card, wherein a vertical level of a lower surface of the lower plate is lower than a vertical level of a lower surface of the probe pin, and wherein the lower plate surrounds an outer circumferential surface of the probe pin, and does not cover the lower surface of the probe pin.

According to another aspect of the inventive concept, there is provided a substrate testing apparatus including a housing including an opening in a portion of an upper plate of the housing, a substrate support including a first surface configured to support a substrate and a second surface opposite to the first surface, and a photographing hole penetrating the first surface and the second surface, a camera arranged in an inner space of the housing below the second surface of the substrate support, and configured to photograph skeleton chips through the photographing hole of the substrate support when the skeleton chips are disposed on the substrate support, a lens arranged on an upper portion of the camera, a probe device arranged above the substrate support, and configured to apply a voltage to the skeleton chips, and a logic tester, a probe interface board, and an interface unit connected to an upper portion of the probe device, wherein the probe device includes a probe pin configured to contact a chip bump arranged on an upper surface of a skeleton chip, a probe card in contact with an upper surface of the probe pin, a lower plate arranged under a lower surface of the probe card, and a support protrusion arranged under the lower plate, and configured to be detachable, and wherein a vertical level of a lower surface of the support protrusion is lower than a vertical level of a lower surface of the probe pin, wherein the probe device includes a hole on a lower portion of the probe device, wherein the hole is a space surrounded by a lower surface of the probe pin and the support protrusion and configured such that the chip bump is inserted in the hole, wherein the probe device is configured to uniformly apply pressure onto an entirety of a chip contact surface of the skeleton chip when the probe device is in contact with the skeleton chip, wherein the chip contact surface is a region of an upper surface of the skeleton chip except for a region where chip bumps are disposed, and wherein the lower plate and the support protrusion are configured such that a sum of respective lengths in a vertical direction of the lower plate and the support protrusion is the same as a sum of respective lengths in the vertical direction of the probe pin and the chip bump.

### BRIEF DESCRIPTION OF THE DRAWINGS

Embodiments will be more clearly understood from the following detailed description taken in conjunction with the accompanying drawings in which:

FIG. 1 is a cross-sectional view of a substrate testing apparatus according to an embodiment;

FIG. 2A is an enlarged view of region A in FIG. 1 according to an embodiment;

FIG. 2B is an enlarged view of region A in FIG. 1 according to another embodiment;

FIG. 2C is an enlarged view of region A in FIG. 1 according to another embodiment;

FIG. 3A is a diagram illustrating a scene in which a skeleton chip is in contact with a probe device in FIG. 2A;

FIG. 3B is a diagram illustrating a scene in which a skeleton chip is in contact with a probe device in FIG. 2B;

FIG. 4A is an enlarged view of region B in FIG. 3A;

FIG. 4B is an enlarged view of region C in FIG. 3B;

FIG. 5 is a plan view from below of a skeleton chip according to an embodiment;

FIG. 6 is a plan view from above of a skeleton chip according to an embodiment;

FIG. 7 is a plan view from below of a portion of a probe device, according to an embodiment;

FIG. 8 is a plan view from below of a state in which a probe device is in contact with a skeleton chip, according to an embodiment;

FIGS. 9 through 13 are plan views from below of a state in which a probe device is in contact with a skeleton chip, according to embodiments; and

FIG. 14 is a signal flow diagram of a substrate testing apparatus according to an embodiment.

### DETAILED DESCRIPTION OF THE EMBODIMENTS

Because various changes can be applied to the embodiments and the embodiments can have various types, some embodiments are illustrated in the drawings and detailed descriptions thereof are provided. However, the embodiments are not intended to limit the inventive concept to the embodiments. In addition, embodiments to be described below are only examples and various modifications from such embodiments may be possible.

The use of all examples or example terms is simply for describing a technical idea in detail, and the scope of the present disclosure is not limited by these examples or example terms unless contexts indicate otherwise.

Unless otherwise specified, in the inventive concept, a vertical direction may be defined as a Z direction, and a first horizontal direction and a second horizontal direction may be defined as horizontal directions which are perpendicular to the Z direction. The first horizontal direction may be referred to as an X direction, and the second horizontal direction may be referred to as a Y direction. A vertical level may be referred to as a height level in a vertical direction (Z direction). A horizontal width in the first horizontal direction or the second horizontal direction may be referred to as a length in the horizontal directions (X direction and/or Y direction), and a vertical length may be referred to as a length in the vertical direction (Z direction).

Spatially relative terms, such as “beneath,” “below,” “lower,” “above,” “upper,” “top,” “bottom,” “front,” “rear,” “horizontal,” “vertical,” and the like, may be used herein for ease of description to describe positional relationships, such as illustrated in the figures, for example. It will be understood that the spatially relative terms encompass different orientations of the device in addition to the orientation depicted in the figures.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

It will be understood that when an element is referred to as being "connected" or "coupled" to or “on” another element, it can be directly connected or coupled to or on the other element or intervening elements may be present. In contrast, when an element is referred to as being "directly connected" or "directly coupled" to another element, or as “contacting” or “in contact with” another element (or using any form of the word “contact”), there are no intervening elements present at the point of contact.

As used herein, components described as being “electrically connected” are configured such that an electrical signal can be transferred from one component to the other (although such electrical signal may be attenuated in strength as it is transferred and may be selectively transferred).

Throughout the specification, when a component is described as "including" a particular element or group of elements, it is to be understood that the component is formed of only the element or the group of elements, or the element or group of elements may be combined with additional elements to form the component, unless the context clearly and/or explicitly describes the contrary.

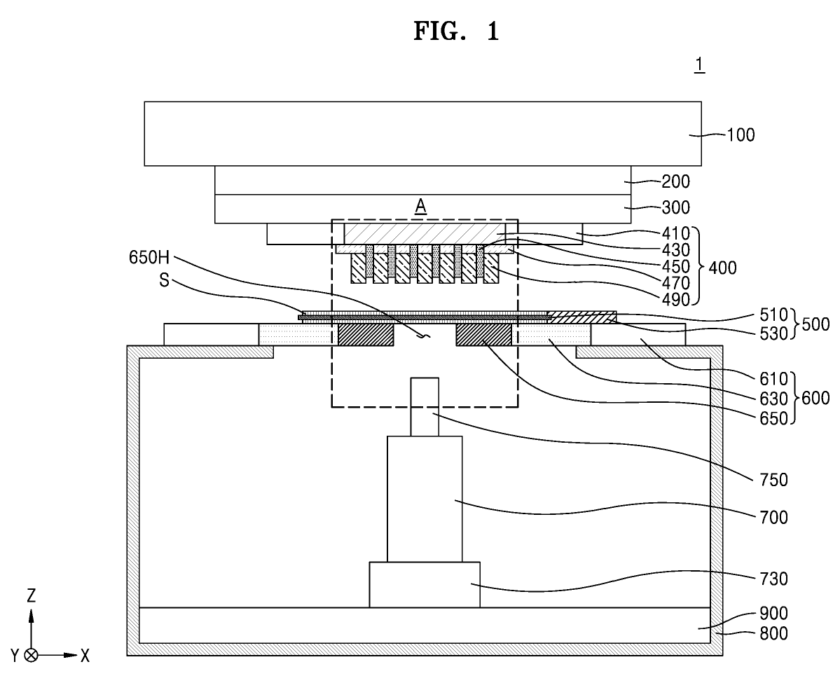

FIG. 1 is a cross-sectional view of a substrate testing apparatus 1 according to an embodiment.

Referring to FIG. 1, the substrate testing apparatus 1 according to an embodiment may include or may be an apparatus to test defects of a substrate S. The substrate testing apparatus 1 may include or may be an apparatus for performing a hot electron analysis (HEA) test to detect/test a stand-by defects of a skeleton chip included in the substrate S. The stand-by defects of the substrate S may be various types of defects occurring/existing in the stand-by state of the substrate S and/or chips in the substrate S. For example, the stand-by defects of the substrate S may include a leakage current generated by or flowing through a PN junction, an oxide layer, or the like, in the stand-by state of the substrate S and/or chips in the substrate S.

Skeleton chips described as inspection objects in the present disclosure may be remaining chips after grinding a back side of the substrate and assembling chips (hereinafter, referred to as pass chips) that have passed an electrical die sorting (EDS) test process of evaluating electrical characteristics and identifying the functionality of chips. The skeleton chips may be chips attached to tapes of similar size to the substrate, and each tape may attach only skeleton chips and not the pass chips.

The skeleton chips may form a fail map on the tape that shows positions and kinds of fails in the inspection. As described above, a substrate including only fail chips on the tape may be a skeleton substrate. The skeleton chip may have a thickness that is different from the pass chips in the vertical direction. In an embodiment, a pass chip may have a thickness of about 700 micrometers to about 800 micrometers. In an embodiment, the skeleton chip may have a thickness of about 100 micrometers to about 200 micrometers less than that of the pass chip. Because, as described above, the thicknesses of the skeleton chips may be less than the thicknesses of general pass chips, when an inspection by using a probe device is performed, an inspection device and method different from those for the pass chips may be required. In an embodiment, the probe device may reduce a pressure applied to the skeleton chip to be lower than a pressure applied to the pass chip. To lower the pressure, because it is difficult to reduce the force itself applied to the bump unit arranged on a chip, it may be necessary to increase the area of the chip to reduce pressure applied per unit area.

In an embodiment, the HEA test may include a test for determining whether a test portion of the substrate S is defective, by applying a voltage to the skeleton chip, which is the test portion of the substrate S, and photographing photon emission and/or heat emission generated by the skeleton chip of the substrate S by using a camera.

In addition, the substrate testing apparatus 1 may determine stand-by defects, such as generation of a leakage current in the portion described above of the substrate S, by referring to images related to photon emission and/or heat emission photographed from the skeleton chip, which is the test portion of the substrate S.

The substrate S tested by the substrate testing apparatus 1 may include a semiconductor substrate. For example, the substrate S may include or may be a wafer including circuit patterns formed of a plurality of layers. As described above, the wafer may include or may be a skeleton wafer including the skeleton chip.

Referring to FIG. 1, the substrate testing apparatus 1 according to an embodiment may include a logic tester 100, a probe interface board (PIB) 200, and an interface unit 300.

According to an embodiment, the logic tester 100 may include a pattern generator configured to generate an input signal pattern provided to the device to be tested, a timing controller configured to synchronize the timing of the signal with the clock speed of the device, a comparator configured to determine a test result by comparing signals output by the device, a data capture unit configured to record data generated during the test, a memory system for storing vector data of input and output signals, a power supply device configured to supply various voltages and currents required in a test environment to the device, etc. According to an embodiment, the logic tester 100 may analyze input and output signals of a logic device to evaluate whether the logic device operates normally, or determine the device output that does not match an expected value as a defect.

According to an embodiment, the PIB 200 may include a signal routing circuit electrically connecting the logic tester 100 and a probe card to transmit signals between them, a power distribution network that transmits power to a particular region of the wafer, a temperature control device that controls thermal effects during the wafer test, etc. According to an embodiment, the PIB 200 may be configured to transmit a signal generated by the logic tester 100 to a particular chip on the wafer, or to transmit a signal output by the wafer to the logic tester 100.

According to an embodiment, the interface unit 300 may include a signal converter that converts a signal format between the logic tester 100 and the PIB 200, a signal amplifier that amplifies a weak signal to enable accurate reading, etc. For example, the interface unit 300 may be an interface board. In certain embodiments, the PIB 200 and the interface unit 300 may be integrated to form one interface board. For example, the PIB 200 and the interface unit 300 may be attached together with an adhesive to form the one integrated interface board. In certain embodiments, circuits/functions of the PIB 200 and the interface unit 300 may be formed in one integrated interface board such that boundaries between the PIB 200 and the interface unit 300 are not clear.

The substrate testing apparatus 1 may include a probe device 400, a substrate moving device 500, a support unit 600 supporting the substrate S, and a camera 700.

The support unit 600 may include a first surface supporting the substrate S and a second surface opposite to the first surface. The support unit 600 according to an embodiment may include a photographing hole 650H penetrating the first surface and the second surface. The support unit 600 may be a substrate support.

The support unit 600 may include a support plate 610 at the outermost portion thereof, a round insert 630 connected to the support plate, and a window plate 650 arranged at the center thereof. The photographing hole 650H may be arranged at the center of the window plate 650.

An upper surface of the support plate 610 may support a portion of the substrate S. For example, when the substrate S is moved on the upper surface of the support plate 610 by the substrate moving device 500 in the horizontal direction, the upper surface of the support plate 610 may support a portion of the substrate S. The support unit 600 including the support plate 610, the round insert 630, and the window plate 650 may be an embodiment, and in the following descriptions, an open-type support unit 600a is mainly described as an embodiment of the support unit 600 optimized for the inspection of the skeleton chip.

The substrate moving device 500 may be configured to move the substrate S on the support plate 610 in the horizontal direction. The substrate moving device 500 may include a substrate fixing unit 510 for fixing the substrate S and a substrate moving unit 530 for moving the substrate S.

In an embodiment, the substrate fixing unit 510 of the substrate moving device 500 may have a ring shape surrounding the edge or a periphery of the substrate S. The substrate fixing unit 510 may have a ring shape having a substrate fixing hole, and a cross-section of the substrate fixing hole may be greater than a cross-section of the substrate S. Accordingly, an inner surface of the substrate moving device 500 may surround the edge of the substrate S arranged in the substrate fixing hole.

In addition, when the substrate S is arranged in the substrate fixing hole, the substrate S may be temporarily coupled to the substrate fixing unit 510 by an adhesive member such as an adhesive tape. For example, when the HEA test is performed, the substrate S may be coupled to the substrate fixing unit 510 by an adhesive member, and after the HEA test is performed, the substrate S may be separated from the substrate fixing unit 510 by removing the adhesive member.

In an embodiment, the substrate moving unit 530 of the substrate moving device 500 may have a rod shape connected to the outer surface of the substrate fixing unit 510. One side of the substrate moving unit 530 may be connected to the substrate fixing unit 510, and the other side of the substrate moving unit 530 may be connected to an actuator for moving the substrate moving device 500. For example, an actuator may include a combination of a motor and a gear, and the actuator may include a driving source that generates power to move the substrate moving device 500 on the support plate 610 in the horizontal direction. For example, the substrate fixing unit 510 may be a substrate holder, e.g., a substrate chuck, and the substrate moving unit 530 may be a robotic arm connected to an outer surface of the substrate holder 510 and configure to move the substrate holder 510. The substrate holder 510 may be an electrostatic chuck, a vacuum chuck, or a mechanical substrate chuck. The driving source may be electric power.

The probe device 400 may include or may be a device which is on the substrate S and is configured to apply a voltage to a portion of the substrate S for a stand-by defect test of the substrate S. According to an embodiment, the probe device 400 may include a pogo block 410, a probe card 430, a probe pin 450, a lower plate 470, a support protrusion unit 490, etc.

The pogo block 410 of the probe device 400 may include a substrate on which circuit patterns are formed. For example, the pogo block 410 may include a printed circuit board which connects a test head to the probe card 430.

In an embodiment, the pogo block 410 may receive an electrical signal from a tester head and transmit the electrical signal to the probe card 430. For example, the pogo block 410 may include a plurality of pogo pins in contact with the probe card 430.

The probe card 430 of the probe device 400 may be configured to transmit the electrical signal transmitted by the pogo block 410 to the probe pin 450.

In addition, the probe pin 450 of the probe device 400 may include a pin in contact with one of the skeleton chips included in the substrate S, e.g., while a test is performed. For example, the probe pin 450 may include a pogo pin-type pin which elastically expands and contracts.

In an embodiment, one side/end of the probe pin 450 may be connected to the probe card 430, and the other side/end thereof may be in contact with a portion of the substrate S, e.g., while a test is performed. For example, the shape of the probe pin 450 is illustrated as a rod shape with a constant diameter in the drawing, but may have a needle shape in which the diameter of the probe pin 450 decreases in a downward direction.

In addition, the probe pin 450 may include a metal material to apply a voltage to a portion of the substrate S. For example, the probe pin 450 may include tungsten, platinum, etc. However, the material of the probe pin 450 is not limited thereto.

The camera 700 may be placed below the support unit 600, and may be configured to photograph a skeleton chip that is a test portion of the substrate S exposed by the photographing hole 650H of the support unit 600. In an embodiment, the camera 700 may photograph a lower surface of the skeleton chip included in the substrate S or the inside of the skeleton chip overlapped with the lower surface of the skeleton chip in the vertical direction.

As the number of pattern layers in the substrate S increases, it may be difficult to detect defects occurring/existing in a first pattern layer arranged in a lower portion of the substrate S. For example, when the inside of the substrate S is photographed by using a camera arranged above the substrate S, the first pattern layer of the substrate S may be covered by a plurality of pattern layers arranged above the first pattern layer. Accordingly, defects of the first pattern layer of the substrate S may not be detected/photographed by the camera 700.

The camera 700 according to an embodiment may be arranged below the support unit 600, and may photograph the skeleton chip included in the substrate S exposed by the photographing hole 650H of the support unit 600. Accordingly, the camera 700 may easily detect defects occurring/existing in the pattern layer arranged at a lower portion of the skeleton chip.

In an embodiment, the camera 700 may include or may be a photo emission microscope (PHEMOS) device configured to photograph the photon emission occurring inside the skeleton chip of the substrate S. For example, the PHEMOS device may be a PHEMOS camera. For example, the PHEMOS device may photograph the photon emission from the skeleton chip of the substrate S to which the voltage is applied, and detect the leakage current generated or flowing through at a PN junction, an oxide layer, or the like, in the stand-by state of the substrate S.

In an embodiment, the camera 700 may also include or may be a thermal emission microscope (THEMOS) device configured to photograph thermal emission occurring inside the skeleton chip of the substrate S. For example, the THEMOS device may be a THEMOS camera. For example, the THEMOS device may photograph heat generated by the skeleton chip of the substrate S to which the voltage is applied, and detect short points, abnormal resistance, and contact defects, or the like, in the stand-by state of the substrate S.

In an embodiment, the camera 700 may include or may be an InGaAs camera including a compound semiconductor including indium, gallium, and arsenide, or an InSb camera including a compound semiconductor including indium and antimony.

For example, when the camera 700 includes or is an InGaAs camera, the camera 700 may photograph an optical image generated by the skeleton chip of the substrate S to which a voltage is applied. In addition, when the camera 700 includes or is the InSb camera, the camera 700 may also capture a thermal image generated by the skeleton chip of the substrate S to which a voltage is applied.

In addition, camera 700 may not be limited to the type of camera described above, but may also include or may be a high performance camera, such as a charge-coupled device (CCD) camera.

A camera driving device 730 may include or may be a device configured to move the camera 700 in at least one of the horizontal directions and the vertical direction.

In an embodiment, the camera driving device 730 may include a moving stage for driving the camera 700. For example, the camera driving device 730 may include an X stage for moving the camera 700 in the X direction, a Y stage for moving the camera 700 in the Y direction, and a Z stage for moving the camera 700 in the Z direction. Each of the X stage, Y stage, and Z stage of the camera driving device 730 may be connected to an actuator such as a motor.

A lens 750 may be arranged between the camera 700 and the support unit 600, and may be configured to refract light emitted by the camera 700. For example, the lens 750 may collect or disperse light to adjust the position where the light emitted by the camera 700 is condensed on the substrate S.

In an embodiment, when the camera 700 includes or is an InGaAs camera or an InSb camera, the lens 750 may include or may be an infrared (IR) lens that refracts light in an infrared wavelength band.

In an embodiment, the lens 750 may include a plurality of lenses having different refractive indices. For example, any one of the plurality of lenses may be selected to adjust the position where the light emitted by the camera 700 is concentrated in the substrate S.

The substrate testing apparatus 1 may include a housing 800. A portion of an upper surface/plate of the housing 800 may be open. For example, an opening may be formed in the upper plate of the housing 800. The housing 800 may have an inner space, and the inner space may be defined by the upper surface/plate, side surfaces/walls, and a lower surface/plate of the housing 800.

In an embodiment, the housing 800 may be moved. For example, the housing 800 may be moved e.g.., with respect to the logic tester 100 and/or with respect to the probe device 400, by using a moving member such as a wheel attached to the lower surface/plate of the housing 800. However, the embodiment is not limited thereto, and the housing 800 may also be fixed.

In an embodiment, the camera 700, the camera driving device 730, the lens 750, an anti-vibration device 900, or the like may be arranged in the inner space of the housing 800. In addition, the support unit 600 may be arranged on the upper surface/plate of the housing 800.

The anti-vibration device 900 may be configured to prevent vibration of the camera 700, the camera driving device 730, and the lens 750. The anti-vibration device 900 may alleviate a phenomenon in which the camera 700, the camera driving device 730, and the lens 750 vibrate due to an external impact applied to the housing 800. For example, the anti-vibration device 900 may include at least one of a spring, an anti-vibration rubber, and a hydraulic cylinder.

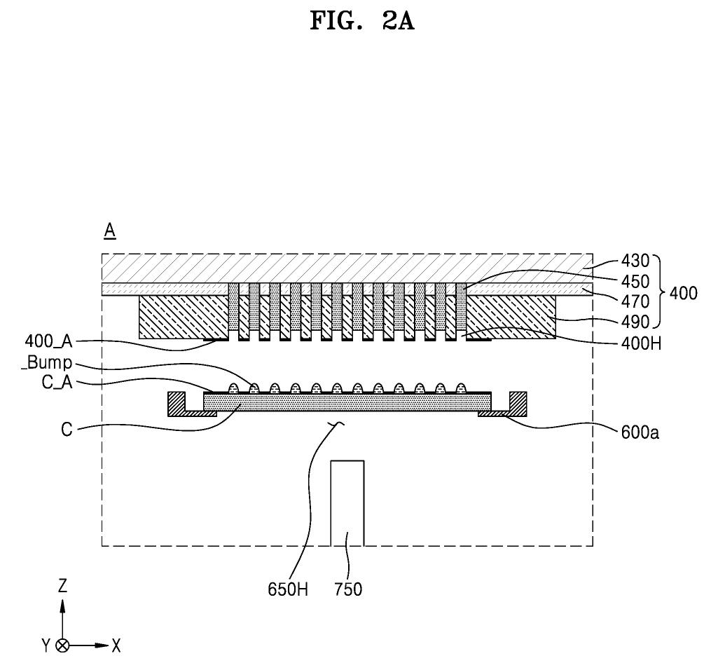

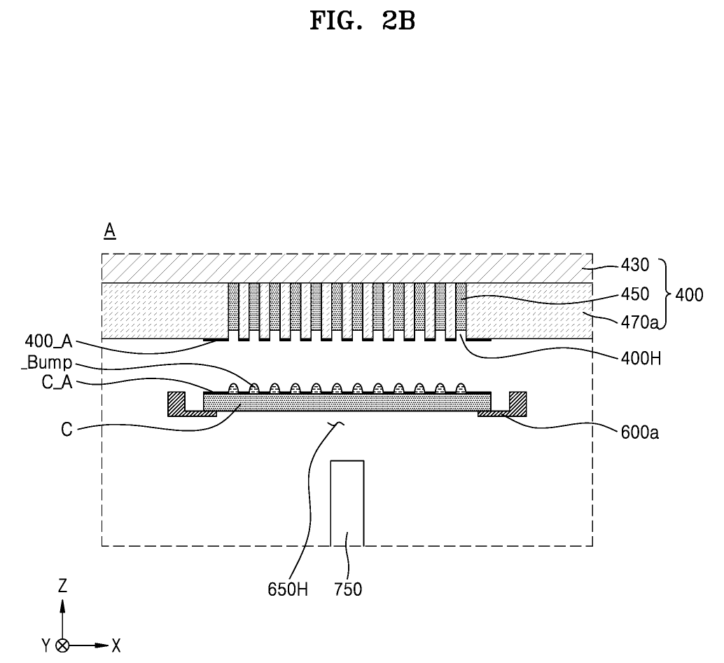

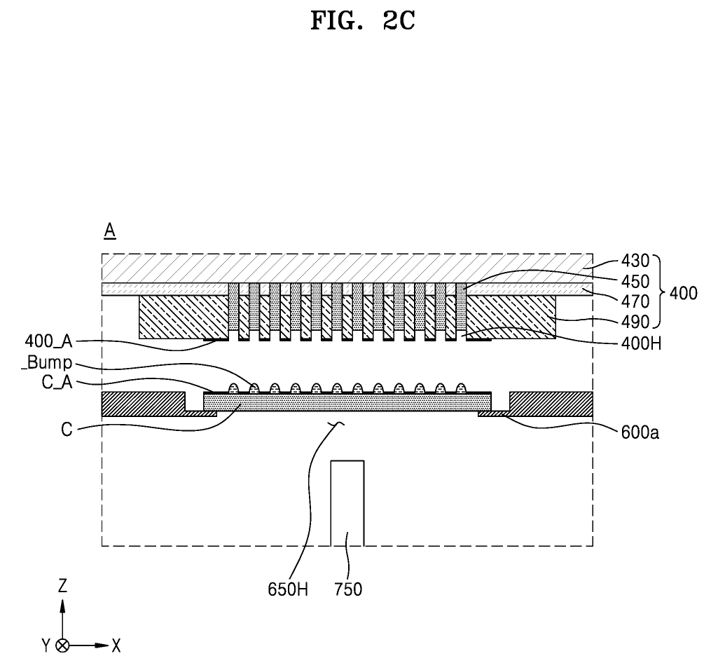

FIG. 2A is an enlarged view of region A in FIG. 1 according to an embodiment.

The embodiment illustrated in FIG. 2A is described below with reference to FIG. 1 together.

The lower plate 470 included in the probe device 400 according to an embodiment may be arranged under a lower surface of the probe card 430. The probe device 400 may include the support protrusion unit 490, which is arranged under the lower plate 470 and is configured to be detachable. A vertical level of the lower surface of the support protrusion unit 490 may be lower than a vertical level of a lower surface of the probe pin 450. Accordingly, when a skeleton chip C rises, a chip contact surface C_A, which is a portion of an upper surface of the skeleton chip C, may be in contact with a probe device contact surface 400_A, which is a portion of the lower surface of the support protrusion unit 490, and not in contact with the probe pin 450. The probe pin 450 may be in contact with a chip bump unit C_Bump arranged on the upper surface of the skeleton chip C. When the probe device 400 and the skeleton chip C are in contact with each other and exert an action/reaction force (e.g., a pressure) to each other, the probe device 400 may not only apply a force to the chip bump unit C_Bump of the skeleton chip C by using only the probe pin 450, but apply a force to the skeleton chip C by using the support protrusion unit 490. Chip bump units C_Bump described in the present disclosure may be bumps formed on a surface of a skeleton chip C. The support protrusion unit 490 described in the present disclosure may be a support protrusion disposed under the lower plate 470 of the probe 400.

In the probe device 400 according to an embodiment, a hole unit 400H, which is a space in which the chip bump unit C_Bump is inserted, may be formed under a lower portion of the probe pin 450. The hole unit 400H may be surrounded by a lower surface of the probe pin 450 and the support protrusion unit 490. Hole units 400H described in the present disclosure may be holes formed in the probe 400 and configured such that chip bumps C_Bump of a skeleton chip are inserted into the holes 400H while a test of the skeleton chip is performed.

An area of the hole unit 400H in a plan view according to an embodiment may correspond to or the same as an area of the chip bump unit C_Bump in the plan view, and a length in the vertical direction perpendicular to the horizontal direction of the hole unit 400H may be less than or equal to the length of the chip bump unit C_Bump in the vertical direction. The length of the chip bump unit C_Bump in the vertical direction may be formed in a range of about 50 micrometers to about 150 micrometers.

The lower plate 470 may surround the outer circumferential surface of the upper portion of the probe pin 450. The support protrusion unit 490 may also surround the outer circumferential surface of the probe pin 450. The support protrusion unit 490 may not cover the bottom/lower surface of the probe pin 450.

When the probe device 400 is in contact with the skeleton chip C, the probe device 400 may uniformly apply pressure to the entirety of the chip contact surface C_A of the skeleton chip C. The chip contact surface C_A may include a region of the upper surface of the skeleton chip C except for the chip bump unit C_Bump. For example, the probe device contact surface 400_A, which is an area except for the hole unit 400H, of the lower surface of the support protrusion unit 490 may be in contact with the entirety of the chip contact surface C_A of the skeleton chip, e.g., while a test is performed.

In general, only the lower surface of the probe pin 450 has applied a force to the chip bump unit C_Bump, but in the case of the skeleton chip C, because the skeleton chip C is thinner than a general chip, by increasing the area to which a force is applied as described above, the pressure, which is a force applied per unit area, may be relatively reduced. In this way, the skeleton chip C may not bend and/or may not be damaged.

The embodiment disclosed in FIG. 2A may include an open-type support unit 600a. The open-type support unit 600a may support only the outer circumferential surface of the skeleton chip C. The open-type support unit 600a may be configured to support only a partial region of the lower surface of the skeleton chip C. A region of the lower surface of the skeleton chip C that does not overlap the open-type support unit 600a may be exposed, and may be in contact with the lens 750. For example, the open-type support unit 600a may be an open-type substrate support having an opening, e.g., in a middle of the substrate support.

The open-type support unit 600a according to an embodiment may vertically overlap a portion of the support protrusion unit 490. For example, the width of the open-type support unit 600a in a horizontal direction may be less than the width of the support protrusion unit 490 in the horizontal direction. For example, an entire region of the open-type support unit 600a may overlap a partial region of the support protrusion unit 490.

FIG. 2B is an enlarged view of region A in FIG. 1 according to another embodiment.

The embodiment illustrated in FIG. 2B is described below with reference to FIG. 1, mainly with the differences from FIG. 2A.

The probe device 400 shown in FIG. 2B may include a lower plate 470a, but does not include the support protrusion unit 490, e.g., shown in FIG. 2A.

A vertical level of a lower surface of the lower plate 470a formed in one body may be lower than the vertical level of the lower surface of the probe pin 450. Accordingly, when the skeleton chip C rises, the chip contact surface C_A, which is a portion of the upper surface of the skeleton chip C, may be in contact with the probe device contact surface 400_A, which is a portion of the lower surface of the lower plate 470a, and may not contact the probe pin 450. The probe pin 450 may be in contact with a chip bump unit C_Bump arranged on the upper surface of the skeleton chip C. When the probe device 400 and the skeleton chip C are in contact with each other and exert an action/reaction force (e.g., a pressure) to each other, the probe device 400 may not only apply a force to the chip bump unit C_Bump of the skeleton chip C by using only the probe pin 450, but also apply a force to the skeleton chip C by using the lower plate 470a.

In the probe device 400 according to an embodiment, the hole unit 400H, which is the space in which the chip bump unit C_Bump is inserted, may be formed under the lower portion of the probe pin 450. The hole unit 400H may be surrounded by the lower surface of the probe pin 450 and the lower plate 470a. The lower plate 470a may surround the outer circumferential surface of the probe pin 450, and may not cover the bottom/lower surface of the probe pin 450.

The lower plates 470 and 470a and the support protrusion unit 490 illustrated in FIGS. 2A and 2B may be formed differently according to the magnitude/size of the diameter of the skeleton chip C.

FIG. 2C is an enlarged view of region A in FIG. 1 according to another embodiment.

The embodiment illustrated in FIG. 2C is described below with reference to FIG. 1, mainly with the differences from FIG. 2A.

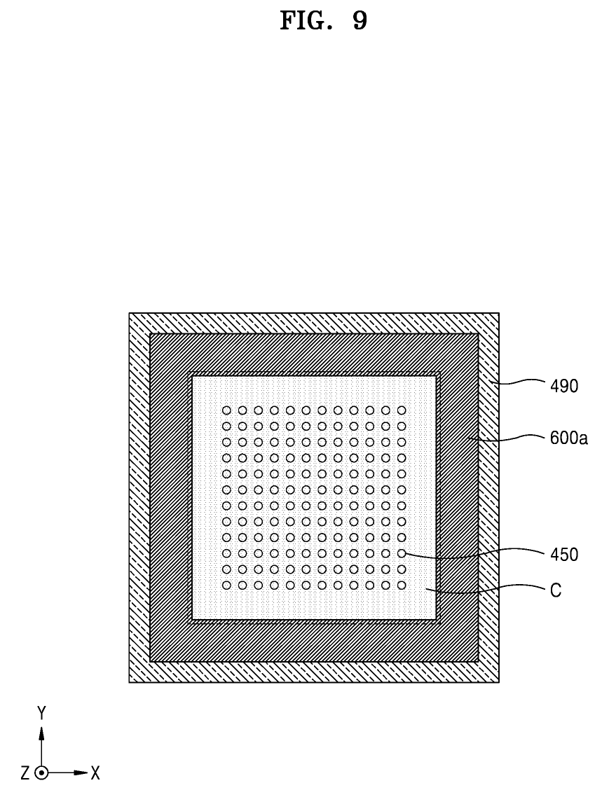

The fact that the open-type support unit 600a illustrated in FIG. 2C exposes the lower surface of the skeleton chip C is the same as that shown in FIG. 2A. The open-type support unit 600a according to an embodiment may vertically overlap the support protrusion unit 490. In addition, the open-type support unit 600a according to an embodiment may vertically overlap a portion of the lower plate 470. An area of the lower plate 470 in in a plan view may be greater than an area of the support protrusion unit 490 in the plan view. For example, a width of the open-type support unit 600a in a horizontal direction may be greater than a width of the support protrusion unit 490 in the horizontal direction, and may be less than or equal to a width of the lower plate 470 in the horizontal direction. Descriptions of the width of the open-type support unit 600a illustrated in FIGS. 2A through 2C are given in detail with reference to plan views of FIGS. 9 through 13.

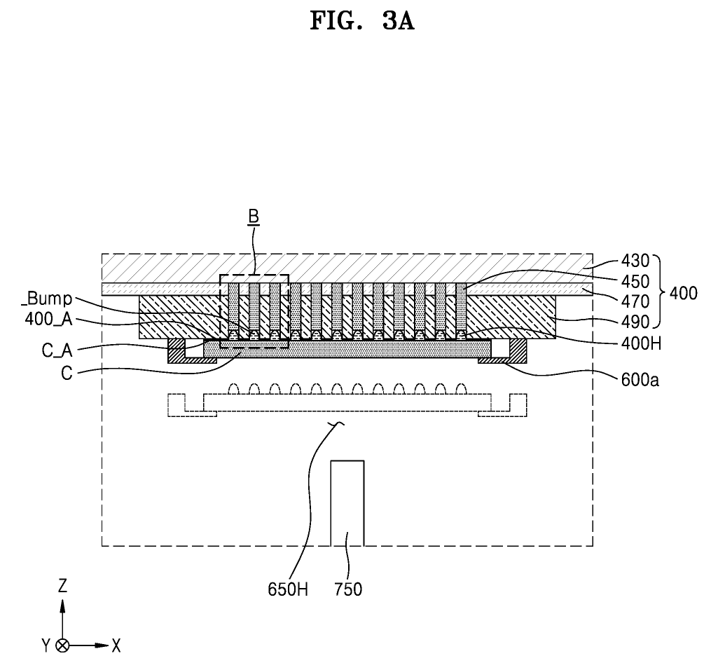

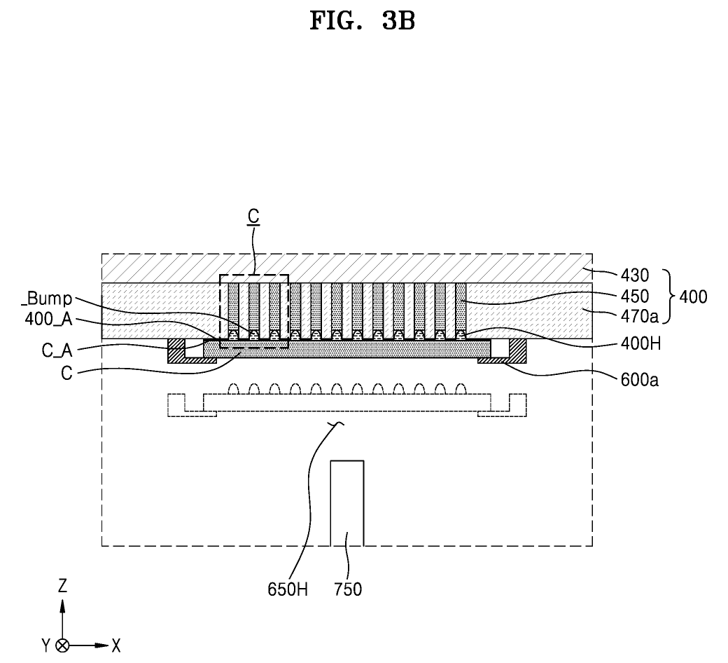

FIG. 3A is a diagram illustrating a scene in which the skeleton chip and the probe device in FIG. 2A are in contact with each other. FIG. 3B is a diagram illustrating a scene in which the skeleton chip and the probe device in FIG. 2B are in contact with each other.

Referring to FIGS. 3A and 3B, after the probe device 400 moves downward, e.g., in a vertical direction, when a portion of the probe device 400 and a portion of the skeleton chip C contact each other, the open-type support unit 600a may be slightly moved up. The subsequent upward movement of the open-type support unit 600a may stop before a broken or bending phenomenon occurs in any portion of the skeleton chip C, and may proceed until the chip bump unit C_Bump and the probe pin 450 contacts each other. In the drawing, only the open-type support unit 600a is shown to have moved, but it should be understood that a fine upward movement of the open-type support unit 600a is performed after the probe device 400 moves downward.

According to the upward movement in which the open-type support unit 600a moves upward, the skeleton chip C may be in contact with the probe device 400.

When the probe device 400 is in contact with the skeleton chip C, the probe device 400 may uniformly apply pressure to the entirety of the chip contact surface C_A of the skeleton chip C. The chip contact surface C_A may include a region of the upper surface of the skeleton chip C except for a region where chip bump units C_Bump are disposed. For example, the probe device contact surface 400_A, which is an area of a bottom surface of the probe device 400 except for a region where hole units 400H are formed, may be in contact with the entirety of the chip contact surface C_A of the skeleton chip C.

The probe device contact surface 400_A in FIG. 3A may be formed differently from the probe device contact surface 400_A in FIG. 3B. In the case of FIG. 3A, the probe device contact surface 400_A may be formed under the bottom surface of the support protrusion unit 490. In the case of FIG. 3B, the probe device contact surface 400_A may be formed under the bottom surface of the lower plate 470.

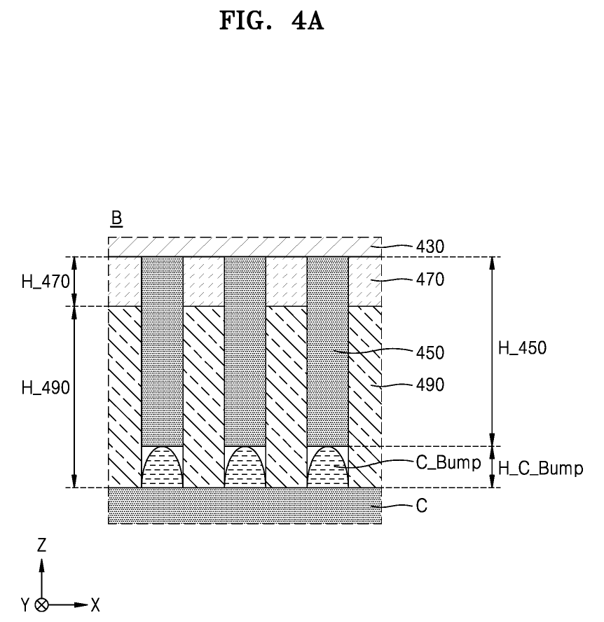

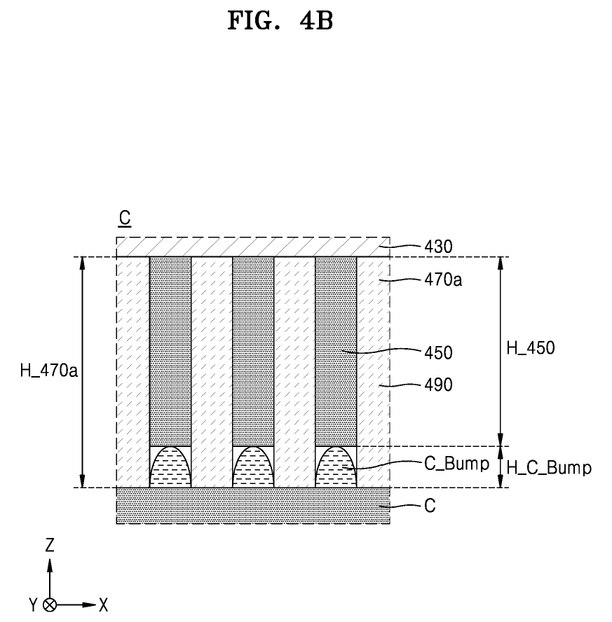

FIG. 4A is an enlarged view of region B in FIG. 3A.

Features of FIG. 4A are described below with reference to FIG. 3A together. The lower plate 470 may have a thickness of H_470 in the vertical direction. The support protrusion unit 490 may have a thickness of H_490 in the vertical direction. The probe pin 450 may have a thickness of H_450 in the vertical direction. The chip bump unit C_Bump may have a thickness of H_C_Bump in the vertical direction. When the skeleton chip C rises, the uppermost end of the chip bump unit C_Bump may be in contact with the lower surface of the probe pin 450.

The sum of H_470 and H_490, which are respectively the lengths in the vertical direction of the lower plate 470 and the support protrusion unit 490, may be the same as the sum of H_450 and H_C_Bump, which are respectively the lengths in the vertical direction of the probe pin 450 and the chip bump unit C_Bump. Accordingly, the lower surface of the support protrusion unit 490 except for the region where the hole units 400H are formed may be in contact with an area of the upper surface of the skeleton chip C except for the region where the chip bump units C_Bump are disposed. In the drawing, although the lower surface of the probe pin 450 is illustrated to be in contact with the uppermost surface of the chip bump unit C_Bump, e.g., without compression, when the length H_450, which is the length in the vertical direction of the probe pin 450, is slightly greater or the lengths of at least one of the lower plate 470 and the support protrusion unit 490 are respectively less than H_470 and H_490, the probe pin 450 may be in contact with the chip bump unit C_Bump while exerting a load on and compress the chip bump unit C_Bump.

FIG. 4B is an enlarged view of region C in FIG. 3B.

Features of FIG. 4B is described below with reference to FIG. 3B together.

A lower plate 470a may have a thickness of H_470a in the vertical direction. The probe pin 450 may have a thickness of H_450 in the vertical direction. The chip bump unit C_Bump may have a thickness of H_C_Bump in the vertical direction. When the skeleton chip C rises, the uppermost end of the chip bump unit C_Bump may be in contact with the lower surface of the probe pin 450.

H_470a, which is a length in the vertical direction of the lower plate 470a, may be the same as the sum of H_450 and H_C_Bump, which are respectively lengths in the vertical direction of the probe pin 450 and the chip bump unit C_Bump. Accordingly, the lower surface of the lower plate 470a except for the region where the hole units 400H are formed may be in contact with an area of the upper surface of the skeleton chip C except for the region where the chip bump units C_Bump are disposed. In the drawing, although the lower surface of the probe pin 450 is illustrated to be in contact with the uppermost surface of the chip bump unit C_Bump, e.g., without compression, when the length H_450, which is the length in the vertical direction of the probe pin 450, is slightly greater or a length in the vertical direction of the lower plate 470a is less than H_470a, the probe pin 450 may be in contact with the chip bump unit C_Bump while exerting a load on and compress the chip bump unit C_Bump.

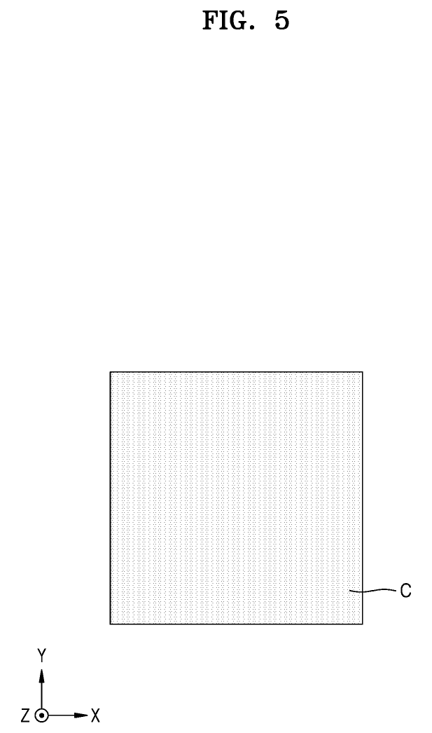

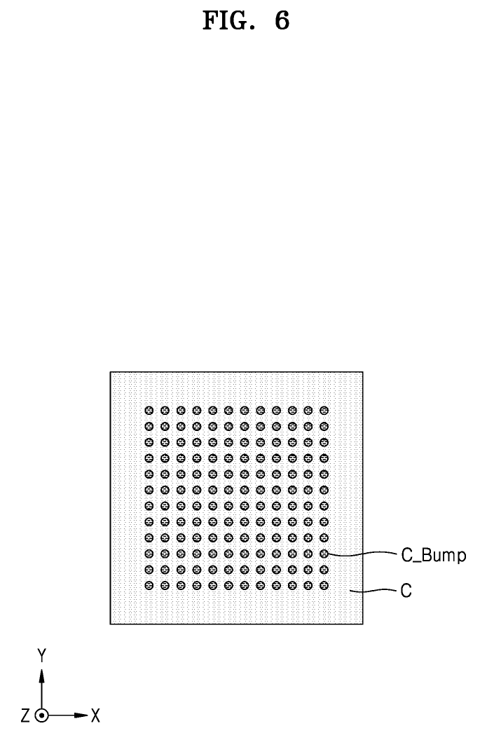

FIG. 5 is a plan view from below of the skeleton chip C according to an embodiment. FIG. 6 is a plan view from above of the skeleton chip C according to an embodiment.

When viewed from below, the skeleton chip C may have a rectangular shape. When viewed from above, a plurality of chip bump units C_Bump may be arranged on the upper surface of the skeleton chip C. The number of chip bump units C_Bump illustrated in FIG. 6 is only an example, and the number of chip bump units C_Bump is not limited thereto. The shape of the upper surface of the chip bump unit C_Bump may be circular, but this is only an example, and may be a square or an ellipse in certain embodiments.

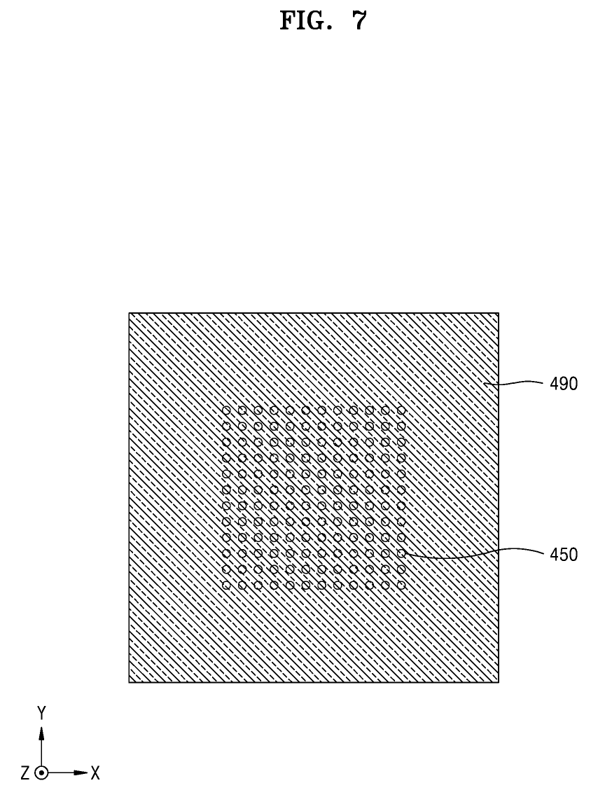

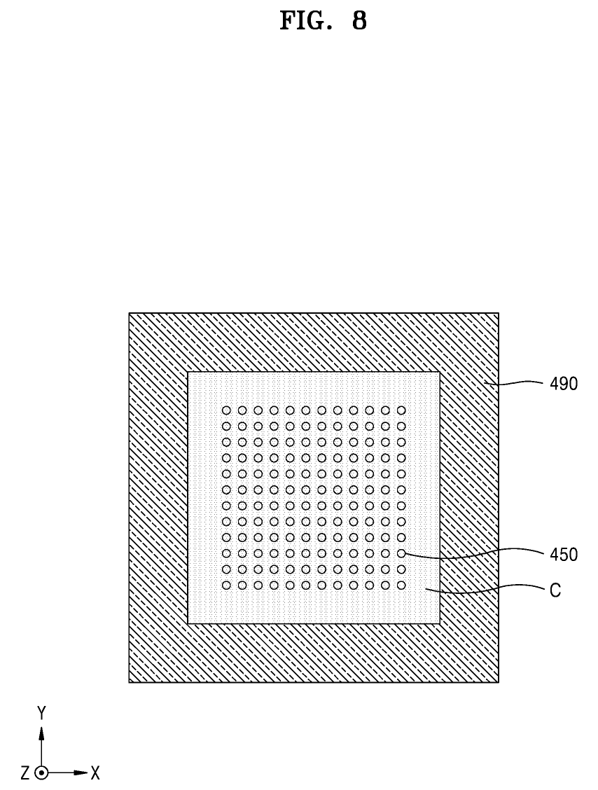

FIG. 7 is a plan view from below of a portion of the probe device 400, according to an embodiment. FIG. 8 is a plan view from below of a state in which the probe device 400 is in contact with the skeleton chip C, according to an embodiment.

Referring to FIG. 7, the hole unit 400H may be formed on the lower surface of the support protrusion unit 490, and a plurality of probe pins 450 with the lower surface exposed through the hole unit 400H may be configured/arranged. The number and positions of the hole units 400H and the probe pins 450 of which the lower surface is exposed through the hole units 400H may correspond to the number and positions of the chip bump units C_Bump described with reference to FIG. 6 such that the chip bump units C_Bump vertically overlap the hole units 400H and the probe pins 450.

Referring to FIG. 8, the skeleton chip C may be coupled to the support protrusion unit 490 to be in contact with the support protrusion unit 490. The upper surface of the skeleton chip C may be in contact with the lower surface of the support protrusion unit 490. An area of the skeleton chip C in a plan view may be less than the area of the support protrusion unit 490 in the plan view. In addition, widths of the skeleton chip C in the first and second horizontal directions (X and Y directions) may be less than widths of the support protrusion unit 490 in the first and second horizontal directions, respectively.

FIGS. 9 through 13 are plan views from below of a state in which the probe device 400 is in contact with the skeleton chip C, according to embodiments.

Referring to FIG. 9, the open-type support unit 600a may overlap a portion of the lower area of the skeleton chip C, e.g., in a vertical direction. The open-type support unit 600a may overlap a portion of the lower area of the support protrusion unit 490, e.g., in the vertical direction. A portion of the lower surface of the skeleton chip C that does not overlap the open-type support unit 600a in the vertical direction may be exposed, e.g., through an open area of the open-type support unit 600a. The open-type support unit 600a may be formed in a frame shape. The widths in the first and second horizontal directions of the open-type support unit 600a may be less than the widths in the first and second horizontal directions of the support protrusion unit 490, respectively.

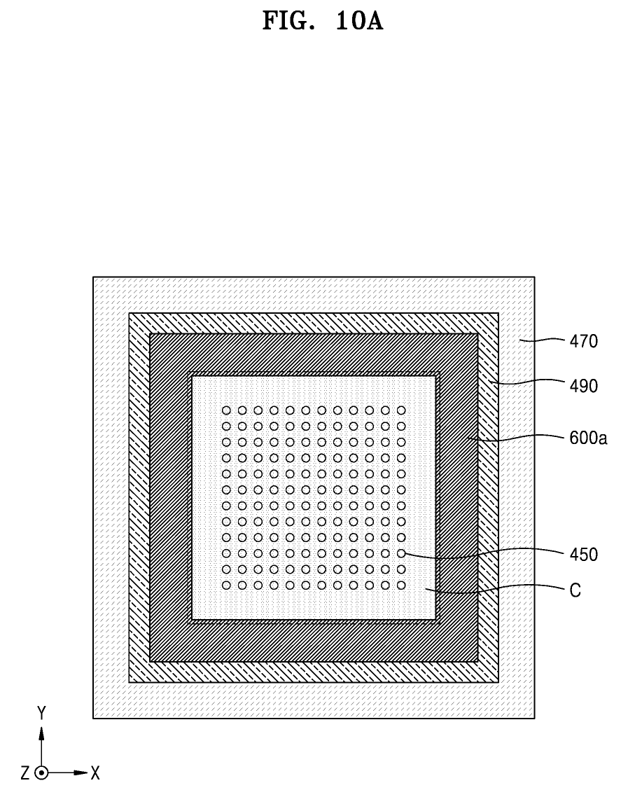

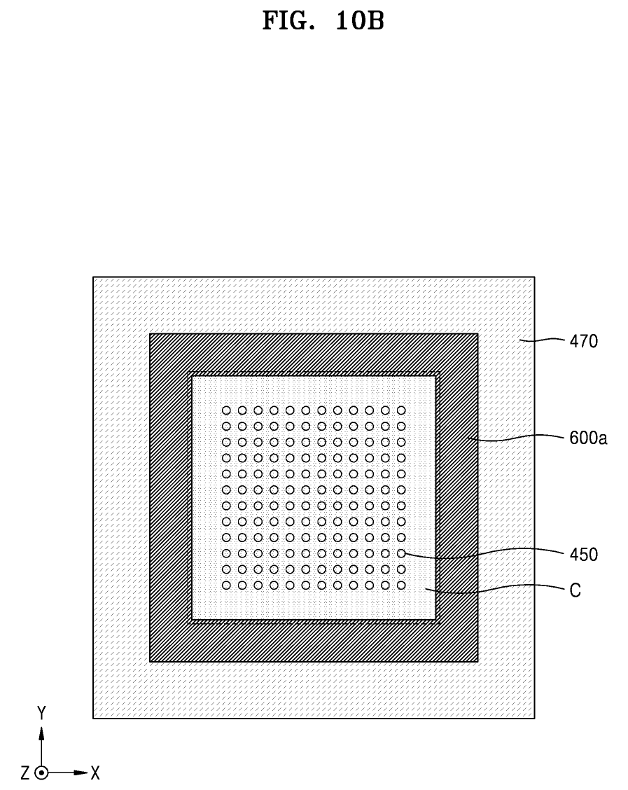

Referring to FIG. 10A, the lower plate 470 may be arranged above the support protrusion unit 490. The embodiment shown in FIG. 10A may correspond to or be the same as the embodiment shown in FIG. 3A, and FIG. 10A is a plan view viewed from below. An area of the lower plate 470 in the plan view may be greater than an area of each of the open-type support unit 600a and the support protrusion unit 490 in the plan view. The open-type support unit 600a may vertically overlap the lower plate 470.

Referring to FIG. 10B, the support protrusion unit 490 may be omitted. The embodiment shown in FIG. 10B may correspond to or be the same as the embodiment shown in FIG. 3B, and FIG. 10B is a plan view viewed from below.

In the case of FIG. 10B also, the widths in the first and second horizontal directions (X and Y directions) of the open-type support unit 600a may be less than the widths in the first and second horizontal directions of the lower plate 470, respectively. In addition, the area of the lower plate 470 in the plan view may be greater than the area of each of the open-type support unit 600a and the support protrusion unit 490 in the plan view.

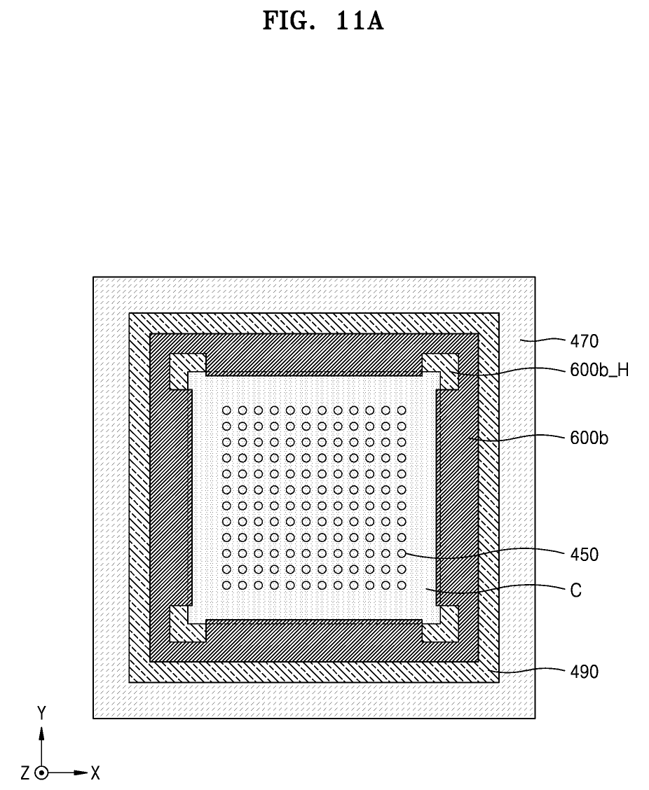

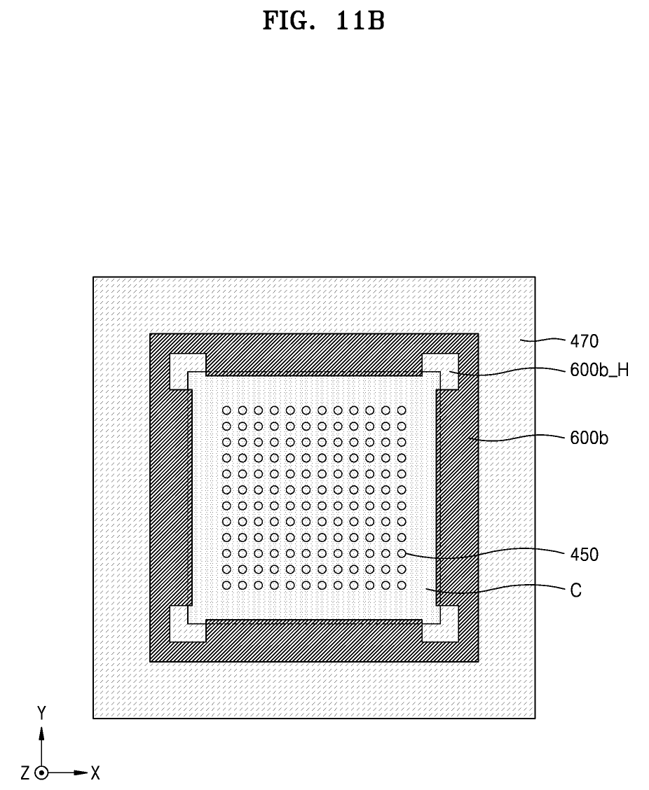

Referring to FIG. 11A, when an open-type support unit 600b overlaps the skeleton chip C, corner unit holes 600b_H may be formed near regions overlapping four corners of the skeleton chip C. A total of four corner unit holes 600b_H may be formed in a region corresponding to an area of the open-type support unit 600b. For example, the four corner unit holes 600b_H of the open-type support unit 600b may vertically overlap four corners of the skeleton chip C, respectively. A plan view shape of the corner unit hole 600b_H is illustrated as a square, but the shape of the corner unit hole 600b_H is not limited thereto. In an embodiment, the shape (e.g., plan view shape) of the corner unit hole 600b_H may be one of a circle, a triangle, a pentagon, and other polygons. However, because the corner unit hole 600b_H is formed regardless of the shape thereof, four apexes of the skeleton chip C may be equally exposed. As the corner unit holes 600b_H are formed, the four apexes of the skeleton chip C may be exposed, and it may be possible to identify whether the probe device 400 is accurately aligned and in contact with the skeleton chip C. The size of the corner unit hole 600b_H may not be limited to that shown in the drawing. For example, the corner unit holes 600b_H described in the present disclosure may be corner holes formed at corners of an opening of an open-type substrate support and configured such that corners of a skeleton chip are exposed through the corner holes when the skeleton chip is placed on the open-type substrate support.

Referring to FIG. 11B, even when the support protrusion unit 490 is omitted, the open-type support unit 600b may include the corner unit holes 600b_H. As the corner unit holes 600b_H are formed, a region near the four vertices of the skeleton chip C and a partial region of the lower plate 470 may be exposed. The shape and size of the corner unit holes 600b_H may be the same as those described with reference to FIG. 11A.

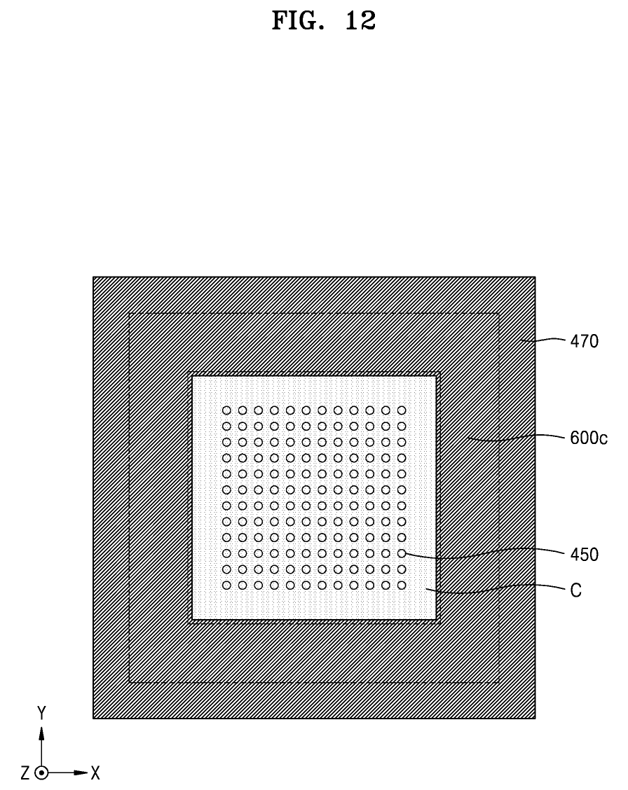

Referring to FIG. 12, an open-type support unit 600c may cover all regions of the area of the lower plate 470. The embodiment shown in FIG. 12 may correspond to or be the same as the embodiment shown in FIG. 2C, and FIG. 12 is a plan view viewed from below.

The widths in the first and second horizontal directions (X and Y directions) of the open-type support unit 600c may be the same as the widths in the first and second horizontal directions of the lower plate 470, respectively. In addition, an area (formed by four outer sides) of the open-type support unit 600c in the plan view may be the same as the area of the lower plate 470 in the plan view. Thus, when viewed from below, the area exposed by the open-type support unit 600c may correspond to or be only the area of the lower surface of the skeleton chip C that does not overlap the open-type support unit 600c.

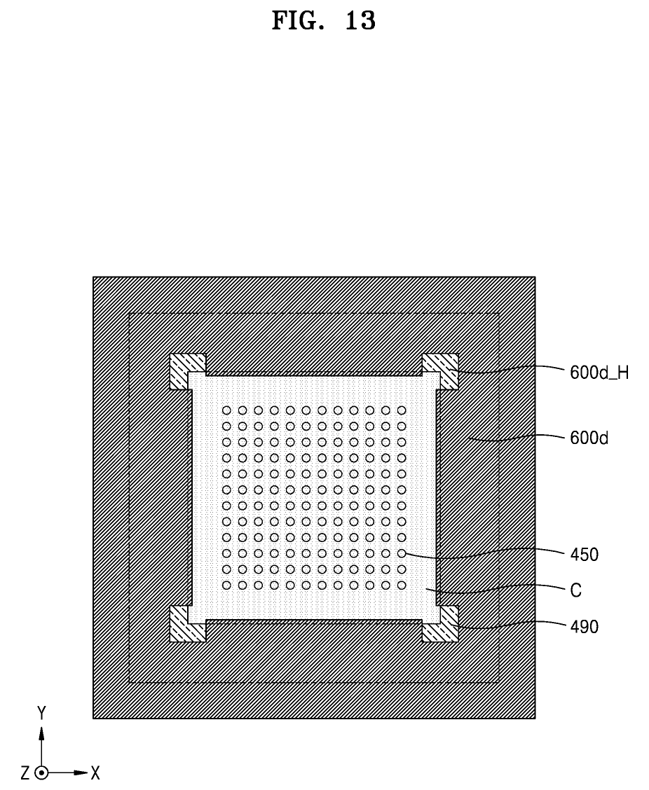

Referring to FIG. 13, an open-type support unit 600d may cover all regions of the area of the lower plate 470. The open-type support unit 600d in FIG. 13 may correspond to or be the same as the open-type support unit 600a in FIG. 2C.

The widths in the first and second horizontal directions (X and Y directions) of the open-type support unit 600d may be the same as the widths in the first and second horizontal directions of the lower plate 470, respectively. In addition, an area (formed by four outer sides) of the open-type support unit 600d in the plan view may be the same as the area of the lower plate 470 in the plan view. Thus, when viewed from below, the area exposed by the open-type support unit 600d may correspond to or may be only the area of the lower surface of the skeleton chip C that does not overlap the open-type support unit 600d.

The open-type support unit 600d may include a corner unit hole 600d_H on each corner of opening. As the corner unit hole 600d_H is formed on each corner, a region near the four vertices of the skeleton chip C and a partial region of the support protrusion unit 490 may be exposed through the corner unit holes 600d_H. When the support protrusion unit 490 is omitted, a partial region of the lower plate 470 may be exposed each corner unit hole 600d_H.

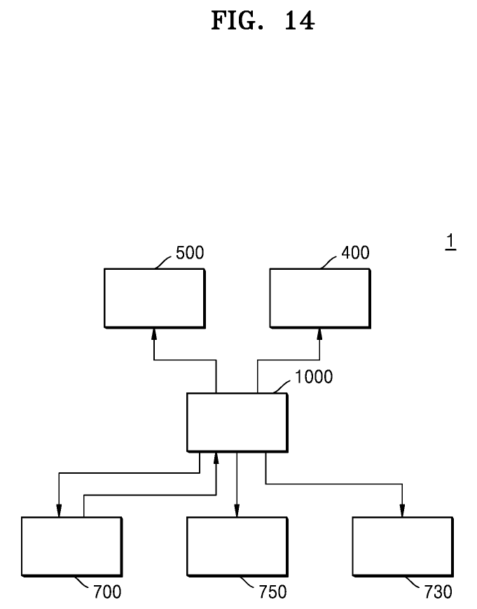

FIG. 14 is a signal flow diagram of the substrate testing apparatus 1 according to an embodiment.

In describing the present embodiment below, FIG. 14 is referred to, together with FIGS. 1 through 13.

The substrate testing apparatus 1 according to an embodiment may include the housing 800, the support unit 600 including the support plate 610, the substrate moving device 500, the probe device 400, the camera 700, the camera driving device 730, the lens 750, the anti-vibration device 900, and a controller 1000.

The technical idea of the support plate 610, the substrate moving device 500, the probe device 400, the camera 700, the camera driving device 730, and the lens 750 of the substrate testing apparatus 1 may be the same as the descriptions given with reference to FIGS. 1 through 13, and the details thereof are omitted.

The housing 800 may be arranged within a process space. The housing 800 may have an inner space, and the inner space may be defined by the upper surface/plate, the side surfaces/walls, and the lower surface/plate of the housing 800. The upper surface/plate of the housing 800 may include a photographing hole 650H exposing at least a portion of the support unit 600 seated on the upper surface/plate of the housing 800.

The controller 1000 may be connected to the substrate moving device 500, the probe device 400, the camera 700, the camera driving device 730, the lens 750, etc.

In an embodiment, the controller 1000 may control the substrate moving device 500 to move the substrate S on the support plate 610. For example, to test a first skeleton chip of the substrate S, the controller 1000 may control the substrate moving device 500 so that the first skeleton chip overlaps the photographing hole 650H.

In addition, to test a second skeleton chip that is different from the first skeleton chip of the substrate S, the controller 1000 may also control the substrate moving device 500 so that the second skeleton chip overlaps the photographing hole 650H.

In an embodiment, the controller 1000 may control the probe device 400 to control the magnitude of a voltage applied to the skeleton chips of the substrate S. In addition, the controller 1000 may control the camera 700, the camera driving device 730, the lens 750, or the like to perform an overall control on the image capturing related to the photon emission and the heat emission.

Even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

While the inventive concept has been particularly shown and described with reference to embodiments thereof, it will be understood that various change in form and details may be made therein without departing from the spirit and scope of the following claims.

What is claimed is:

1. A substrate testing apparatus comprising:
a substrate support including a first surface configured to support a substrate and a second surface opposite to the first surface, and a photographing hole penetrating through the first surface and the second surface;
a camera arranged below the second surface of the substrate support, and configured to photograph skeleton chips through the photographing hole of the substrate support; and
a probe device arranged above the substrate support, and configured to apply a voltage to the skeleton chips,
wherein the probe device comprises:
a probe pin configured to contact a chip bump arranged on an upper surface of a skeleton chip;
a probe card in contact with an upper surface of the probe pin;
a lower plate arranged under a lower surface of the probe card; and
a support protrusion arranged under the lower plate, and configured to be detachable, and
wherein a vertical level of a lower surface of the support protrusion is lower than a vertical level of a lower surface of the probe pin.

2. The substrate testing apparatus of claim 1, wherein the probe device comprises a hole formed under a lower portion of the probe pin and configured such that the chip bump is inserted into the hole.

3. The substrate testing apparatus of claim 2,
wherein an area of the hole in a plan view is the same as an area of the chip bump in the plan view, and
wherein a length in a vertical direction of the hole is less than or equal to a length in the vertical direction of the chip bump.

4. The substrate testing apparatus of claim 2, wherein the support protrusion surrounds an outer circumferential surface of the probe pin, and does not cover a lower surface of the probe pin.

5. The substrate testing apparatus of claim 2, wherein the probe device is configured to uniformly apply pressure onto an entirety of a chip contact surface of the skeleton chip when the probe device is in contact with the skeleton chip, and
wherein the chip contact surface is a region of an upper surface of the skeleton chip except for a region where chip bumps of the skeleton chip are disposed.

6. The substrate testing apparatus of claim 2, wherein the lower plate and the support protrusion are configured such that a sum of respective lengths in a vertical direction of the lower plate and the support protrusion is a same as a sum of respective lengths in the vertical direction of the probe pin and the chip bump.

7. The substrate testing apparatus of claim 1, wherein the substrate support is an open-type substrate support configured to support a partial region of a lower surface of the skeleton chip, and
wherein the open-type substrate support is configured such that a region, not overlapping the open-type substrate support, of the lower surface of the skeleton chip is exposed through an opening formed in the open-type substrate support.

8. The substrate testing apparatus of claim 7, wherein an entire region of the open-type substrate support vertically overlaps a partial region of the support protrusion.

9. The substrate testing apparatus of claim 7, wherein a region of the open-type substrate support vertically overlaps a region of the lower plate.

10. The substrate testing apparatus of claim 7, wherein the open-type substrate support comprises corner holes configured to vertically overlap four corners of the skeleton chip when the skeleton chip is disposed on the open-type substrate support.

11. A substrate testing apparatus comprising:
a substrate support including a first surface configured to support a substrate and a second surface opposite to the first surface, and a photographing hole penetrating the first surface and the second surface;
a camera arranged below the second surface of the substrate support, and configured to photograph skeleton chips through the photographing hole of the substrate support; and
a probe device arranged above the substrate support, and configured to apply a voltage to the skeleton chips,
wherein the probe device comprises:
a probe pin configured to contact a chip bump arranged on an upper surface of a skeleton chip;
a probe card in contact with an upper surface of the probe pin; and
a lower plate arranged under a lower surface of the probe card,
wherein a vertical level of a lower surface of the lower plate is lower than a vertical level of a lower surface of the probe pin, and
wherein the lower plate surrounds an outer circumferential surface of the probe pin, and does not cover the lower surface of the probe pin.

12. The substrate testing apparatus of claim 11, wherein the probe device comprises a hole on a lower portion of the probe device, and
wherein the hole is configured such that the chip bump of the skeleton chip is inserted is a space surrounded by a lower surface of the probe pin and the lower plate.

13. The substrate testing apparatus of claim 12, wherein an area of the hole in a plan view is the same as an area of the chip bump in the plan view, and
wherein a length in a vertical direction of the hole is less than or equal to a length in the vertical direction of the chip bump.

14. The substrate testing apparatus of claim 12,
wherein a probe device contact surface, which is a region of a lower surface of the lower plate except for an area where holes of the probe device are formed, is configured to contact an entirety of a chip contact surface of the skeleton chip, and
wherein the chip contact surface is a region of an upper surface of the skeleton chip, except for a region where chip bumps are formed.

15. The substrate testing apparatus of claim 12, wherein the lower plate is configured such that a length in a vertical direction of the lower plate is a same as a sum of respective lengths in the vertical direction of the probe pin and the chip bump.

16. The substrate testing apparatus of claim 11,
wherein the substrate support is an open-type substrate support configured to support a partial region of a lower surface of the skeleton chip, and
wherein the open-type substrate support is configured such that a region, not overlapping the open-type substrate support, of the lower surface of the skeleton chip is exposed through an opening formed in the open-type substrate support.

17. The substrate testing apparatus of claim 16, wherein the open-type substrate support comprises corner holes formed at corners of the opening and configured to vertically overlap four corners of the skeleton chip when the skeleton chip is disposed on the open-type substrate support.

18. The substrate testing apparatus of claim 11, further comprising a substrate moving device configured to move the substrate in a horizontal direction on the substrate support,
wherein the substrate moving device comprises:
a substrate holder having a ring shape and configured to surround a periphery of the substrate, and
a robotic arm connected to an outer surface of the substrate holder.

19. A substrate testing apparatus comprising:
a housing including an opening in a portion of an upper plate of the housing;
a substrate support including a first surface configured to support a substrate and a second surface opposite to the first surface, and a photographing hole penetrating the first surface and the second surface;
a camera arranged in an inner space of the housing below the second surface of the substrate support, and configured to photograph skeleton chips through the photographing hole of the substrate support when the skeleton chips are disposed on the substrate support;
a lens arranged on an upper portion of the camera;
a probe device arranged above the substrate support, and configured to apply a voltage to the skeleton chips; and
a logic tester, a probe interface board, and an interface unit connected to an upper portion of the probe device,
wherein the probe device comprises:
a probe pin configured to contact a chip bump arranged on an upper surface of a skeleton chip;
a probe card in contact with an upper surface of the probe pin;
a lower plate arranged under a lower surface of the probe card; and
a support protrusion arranged under the lower plate, and configured to be detachable, and
wherein a vertical level of a lower surface of the support protrusion is lower than a vertical level of a lower surface of the probe pin,
wherein the probe device comprises a hole on a lower portion of the probe device,
wherein the hole is a space surrounded by a lower surface of the probe pin and the support protrusion and configured such that the chip bump is inserted in the hole,
wherein the probe device is configured to uniformly apply pressure onto an entirety of a chip contact surface of the skeleton chip when the probe device is in contact with the skeleton chip, wherein the chip contact surface is a region of an upper surface of the skeleton chip except for a region where chip bumps are disposed, and
wherein the lower plate and the support protrusion are configured such that a sum of respective lengths in a vertical direction of the lower plate and the support protrusion is a same as a sum of respective lengths in the vertical direction of the probe pin and the chip bump.

20. The substrate testing apparatus of claim 19,
wherein the substrate support is an open-type substrate support configured to support a partial region of a lower surface of the skeleton chip, and
wherein the open-type substrate support is configured such that a region, not overlapping the open-type substrate support, of the lower surface of the skeleton chip is exposed through an opening formed in the open-type substrate support, and
wherein the open-type substrate support comprises corner holes formed at corners of the opening and configured to overlap four corners of the skeleton chip when the skeleton chip is disposed on the open-type substrate support.
